(19) United States
(12) Patent Application Publication
(10) Pub. No.: US 2021/0302064 A1
(43) Pub. Date: Sep. 30, 2021

(54) MUFFLER AND ELECTRONIC DEVICE

(71) Applicant: FUJITSU LIMITED, Kawasaki-shi (JP)

(72) Inventor: Atsushi Yamaguchi, Kawasaki (JP)

(73) Assignee: FUJITSU LIMITED, Kawasaki-shi (JP)

(21) Appl. No.: 17/154,186

(22) Filed: Jan. 21, 2021

(30) Foreign Application Priority Data
Mar. 26, 2020 (JP) 2020-055631

(51) Int. Cl. F24F 13/24

(52) U.S. Cl. CPC F24F 13/24; F24F 2013/242

(57) ABSTRACT

A muffler provided on an air-blowing side of a fan of a device main body provided with the fan, the muffler includes a duct provided on the air-blowing side of the fan and having a wall portion facing the fan; and a sound absorbing material provided on an inner surface of the wall portion on a side of the fan, wherein a relationship of a<L<{(b−a)/2+a}/n is satisfied where a distance from an end of the fan on a side of the sound absorbing material to an end of the sound absorbing material on a side of the fan is L, a length of a region surface, where the fan is provided, in a short direction is a, and a length of the region surface in a long direction is b, the region surface being of the device main body.

### CROSS-REFERENCE TO RELATED APPLICATION

This application is based upon and claims the benefit of priority of the prior Japanese Patent Application No. 2020-55631, filed on Mar. 26, 2020, the entire contents of which are incorporated herein by reference.

### FIELD

The embodiments discussed herein are related to a muffler and a device provided with the muffler.

### BACKGROUND

To suppress overheating of a device having heat-generating electronic components such as semiconductor elements built-in, there is known a technology of providing a fan that exhausts internal air to a housing of the device or to a frame (also called rack, cabinet, or the like) in which the device is mounted. Moreover, to reduce noise caused by an increase in the size of the fan or an increase in the number of fans or a rotation speed of the fan with an increase in the heating value of the device, there is known a technology of providing a muffler (also called silencer or the like). Regarding the muffler, for example, a method of forming a muffler structure with a sound absorbing material, a method of forming a meandering air flow path in the muffler with a sound absorbing material, a method of pasting a sound absorbing material on an outer frame of the muffler and an inner surface of a member serving as an upper lid, and the like are known. Japanese Registered Utility Model No. 63-182212, Japanese Laid-open Patent Publication No. 2008-269193, and Japanese Laid-open Patent Publication No. 8-44369 are disclosed as related art.

### SUMMARY

According to an aspect of the embodiments, A muffler provided on an air-blowing side of a fan of a device main body provided with the fan, the muffler includes a duct provided on the air-blowing side of the fan and having a wall portion facing the fan; and a sound absorbing material provided on an inner surface of the wall portion on a side of the fan, wherein a relationship of a<L<{(b−a)/2+a}/n is satisfied where a distance from an end of the fan on a side of the sound absorbing material to an end of the sound absorbing material on a side of the fan is L, a length of a region surface, where the fan is provided, in a short direction is a, and a length of the region surface in a long direction is b, the region surface being of the device main body.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views illustrating an example of electronic equipment;

FIGS. 2A and 2B are views for describing an example of an electronic device according to a first embodiment;

FIGS. 3A and 3B are views for describing examples of fans provided in the electronic device according to the first embodiment;

FIGS. 4A and 4B are views for describing an example of blowing air by the fan provided in the electronic device according to the first embodiment;

FIG. 5 is a view for describing an example of the electronic device provided with a muffler according to the first embodiment;

FIGS. 6A and 6B are views for describing a configuration example of a duct of the muffler according to the first embodiment;

FIG. 7 is a view for describing a sound absorbing material provided in the duct of the muffler according to the first embodiment;

FIG. 8 is a diagram illustrating an example of a relationship between a frequency and a normal incidence sound absorption coefficient for sound absorbing materials having different thicknesses;

FIG. 9 is a diagram and a graph illustrating an example of a relationship between a distance from a sound source and attenuation of sound;

FIG. 10 is a graph illustrating an example of measurement results of a sound pressure level of sound generated by the electronic device before and after mounting the muffler;

FIG. 11 is a view for describing an example of an electronic equipment storage box;

FIG. 12 is a view for describing an example of electronic equipment provided with a duct;

FIG. 13 is a view for describing a first modification of the electronic device according to the first embodiment;

FIGS. 14A to 14C are views for describing a second modification of the electronic device according to the first embodiment;

FIG. 15 is a view for describing a first example of a fan unit with a muffler according to a second embodiment;

FIG. 16 is a view for describing a second example of the fan unit with a muffler according to the second embodiment; and

FIG. 17 is a view for describing a third example of the fan unit with a muffler according to the second embodiment.

### DESCRIPTION OF EMBODIMENTS

With a past muffler, if an attempt is made to enhance the muffling effect by increasing an exhaust path length or increasing a volume of the sound absorbing material while ensuring a given exhaust path width, a space for muffling became large and the muffler became large in some cases. Furthermore, when the muffler became large, a device equipped with the muffler also became large, which may limit an installation location.

In view of the foregoing, it is desirable to implement a small muffler and a small device provided with the small muffler.

### First Embodiment

First, an example of electronic equipment and an electronic device will be described.

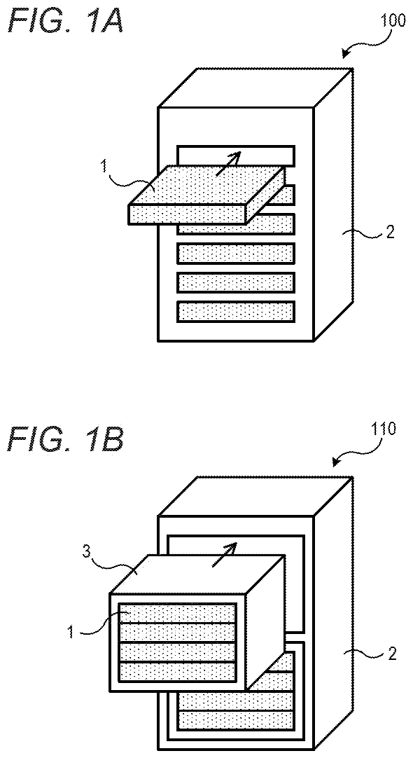

FIGS. 1A and 1B are views illustrating an example of electronic equipment. FIGS. 1A and 1B each schematically illustrate perspective views of a main part of an example of electronic equipment.

Electronic equipment 100 illustrated in FIG. 1A has a structure in which a plurality of flat plate-type electronic devices 1 is mounted in a rack 2 in a stacking manner. The electronic device 1 mounted on the electronic equipment 100 includes, for example, various electronic components including a circuit board such as a motherboard, semiconductor elements mounted on the circuit board, and the like. The electronic device 1 is, for example, an information processing device such as a server computer incorporating electronic components including heat-generating semiconductor elements such as a processor. For example, a 19-inch rack is used for the rack 2, and the electronic device 1 having a thickness of 1U (44.45 mm (outer dimension)), which is the unit standard height, is mounted.

Furthermore, electronic equipment 110 illustrated in FIG. 1B has a structure in which a plurality of flat plate-type electronic devices 1 is housed in a housing 3, and the housings 3 are mounted in the rack 2 in a stacking manner. The electronic device 1 may be mounted in the rack 2 in this way.

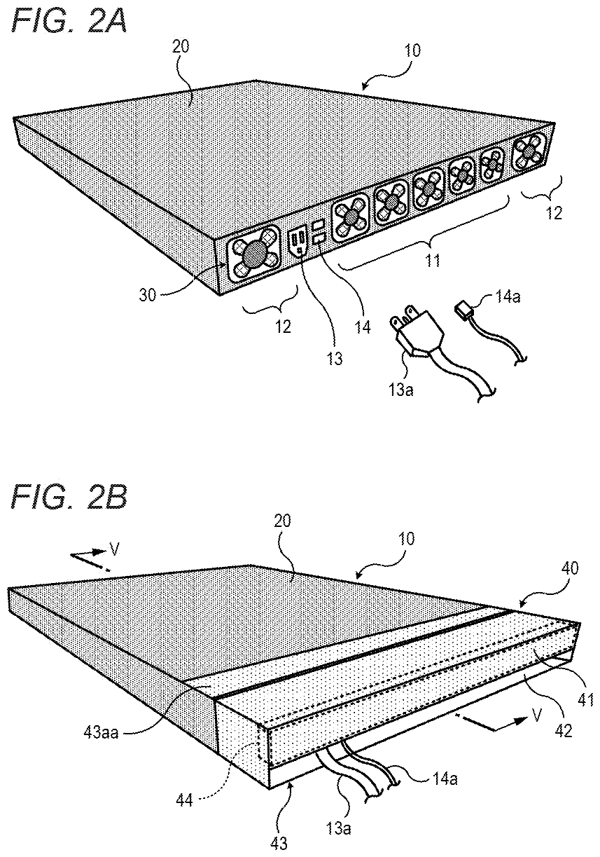

FIGS. 2A and 2B are views for describing an example of an electronic device according to a first embodiment. FIG. 2A schematically illustrates a perspective view of a main part of an example of an electronic device before mounting a muffler. FIG. 2B schematically illustrates a perspective view of a main part of the example of the electronic device after mounting the muffler.

The electronic device 1 includes, for example, an electronic device main body 10 as illustrated in FIG. 2A. Note that the electronic device 1 is a form of a “device”, and the electronic device main body 10 is a form of a “device main body”.

The electronic device main body 10 has a housing 20. The heat-generating electronic components including a circuit board, a semiconductor element mounted on the circuit board, and the like, are built in the housing 20. Here, a depth side of the paper surface of FIG. 2A is a front side of the electronic device main body 10, and a front side of the paper surface of FIG. 2A is a back side of the electronic device main body 10. The electronic device main body 10 includes a fan 30 on the back side thereof, here, seven fans 30, as an example.

For example, the electronic device main body 10 illustrated in FIG. 2A is provided with a system fan region 11 in a center on the back side and a power supply fan region 12 in both ends on the back side across the system fan region 11. In the system fan region 11, a system fan mainly used for cooling the electronic components including heat-generating semiconductor elements including processors such as a central processing unit (CPU) and a digital signal processor (DSP) is provided as the fan 30. In the power supply fan region 12, a power supply fan used for cooling a power supply device (and heat-generating electronic components included therein) that supplies power, converts a voltage, and the like is provided as the fan 30. As an example, FIG. 2A illustrates the electronic device main body 10 provided with five fans 30 in the central system fan region 11 and a total of two fans 30 in the power supply fan regions 12 at both ends, respectively.

Note that the system fan region 11 may be provided with the same or different types of fans 30 as the system fans, and the power supply fan region 12 may be provided with the same or different types of fans 30 as the power supply fans. Furthermore, the system fan region 11 and the power supply fan region 12 may be provided with the same type of fans 30 as each other, or may be provided with different types of fans 30 from each other.

The fan 30 becomes operable when power is supplied from the electronic device main body 10 to which power is supplied from an outside, or when the power is directly supplied from the outside to a unit (fan unit) including the fan 30.

An outlet 13 to which a power cable 13a is connected, a jack 14 to which a communication cable 14a is connected, and the like may be provided on the back side in the electronic device main body 10, in addition to the above fans 30.

The electronic device 1 is provided with a muffler 40 as illustrated in FIG. 2B, for example, on the back side of the electronic device main body 10 provided with the above fans 30 and the like. The muffler 40 has a function to suppress sound generated in the electronic device main body 10, mainly sound of rotation of the fans 30 and sound of a wind generated with the rotation of the fans 30. The muffler 40 includes a duct 43 having a wall portion 41 facing the fans 30 provided on the back side in the electronic device main body 10 with a certain distance. A sound absorbing material 44 is provided on an inner surface of the wall portion 41 facing the fans 30. The duct 43 further includes an opening portion 42 through which the wind from the fans 30 is discharged to the outside. The opening portion 42 is provided facing the fan 30 together with the wall portion 41 on which the sound absorbing material 44 is provided, for example. In the electronic device 1, the muffler 40 having such a configuration is mounted on the back side of the electronic device main body 10, so that the sound generated by the electronic device main body 10 can be suppressed. Note that details of the configuration of the muffler 40 will be described below.

The power cable 13a connected to the above outlet 13 and the communication cable 14a connected to the jack 14 are pulled out through the opening portion 42 of the muffler 40, for example, as illustrated in FIG. 2B.

Next, the fan 30 provided in the electronic device 1 will be described.

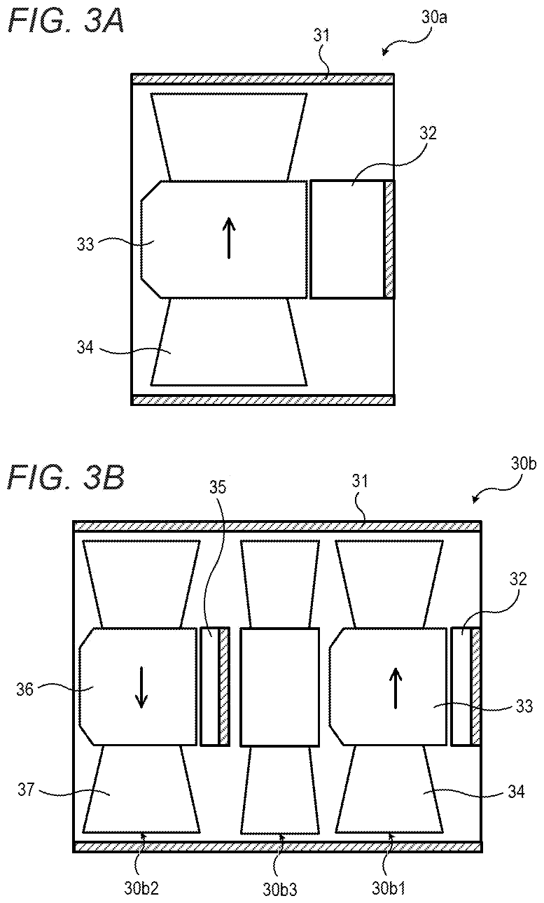

FIGS. 3A and 3B are views for describing examples of the fans provided in the electronic device according to the first embodiment. FIG. 3A schematically illustrates a cross-sectional view of a main part of a first example of the fan. FIG. 3B schematically illustrates a cross-sectional view of a main part of a second example of the fan.

A fan 30a illustrated in FIG. 3A has a casing 31. Inside the casing 31, a motor 32, a cylindrical hub 33 pivotally supported by the motor 32, and a plurality of wings (also referred to as blades, propellers, or the like) 34 provided in a predetermined shape around an outer peripheral surface of the hub 33 are provided. The motor 32 is supported by, for example, the casing 31 (a cover 31b supported by a connection bar 31a to be described below).

In the fan 30a, the hub 33 is rotated as the motor 32 rotates in a predetermined direction, so that the wings 34 provided around the hub 33 are rotated in a predetermined direction. Air is blown from one side of the fan 30a to the other side opposite to the one side toward a direction according to the rotation of the wings 34.

A fan 30b illustrated in FIG. 3B is an example of a counter-rotating fan. The fan 30b includes a moving blade unit 30b1 including the motor 32 provided in the casing 31, the hub 33 pivotally supported by the motor 32, and a plurality of wings 34 provided in a predetermined shape around the hub 33. The fan 30b further includes a moving blade unit 30b2 including a motor 35 provided in the casing 31, a hub 36 pivotally supported by the motor 35, and a plurality of wings 37 provided in a predetermined shape around the hub 36. A stationary blade unit 30b3 is provided between the moving blade unit 30b1 and the moving blade unit 30b2. The motors 32 and 35 are supported by, for example, the casing 31 (the cover 31b supported by the connection bar 31a to be described below).

In the fan 30b, the hub 33 is rotated as the motor 32 rotates in a predetermined direction, so that the wings 34 provided around the hub 33 are rotated in a predetermined direction. The hub 36 is rotated with rotation of the motor 35 in a direction opposite to the motor 32, so that the wings 37 provided around the hub 36 are rotated in a predetermined direction. Air is blown from one side of the fan 30b to the other side opposite to the one side toward a direction according to the rotation of the wings 34 and 37.

In the electronic device 1, the fan 30a as illustrated in FIG. 3A, the fan 30b as illustrated in FIG. 3B, or both the fans 30a and 30b can be used. For example, five fans 30a as illustrated in FIG. 3A can be provided in the system fan region 11 in the center on the back side of the electronic device main body 10 as the fans 30 of the electronic device 1 illustrated in FIG. 2A above. Moreover, a total of two counter-rotating fans 30b as illustrated in FIG. 3B can be provided in the respective power supply fan regions 12 in both ends on the back side in the electronic device main body 10.

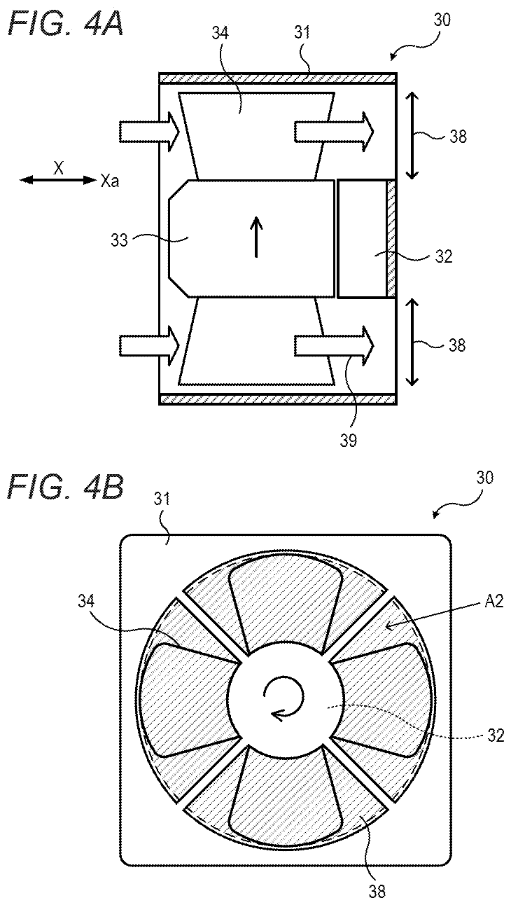

FIGS. 4A and 4B are views for describing an example of air blowing by the fan provided in the electronic device according to the first embodiment. FIG. 4A schematically illustrates a cross-sectional view of a main part of an example of the fan. FIG. 4B schematically illustrates a front view of a main part of the example of the fan.

FIGS. 4A and 4B illustrate the fan 30a illustrated in FIG. 3A above, as an example of the fan 30. In FIG. 4B, the motor 32 is fixed and supported on a back surface (paper surface depth direction) of the cover 31b supported by the four connection bars 31a extending from the casing 31. As illustrated in FIGS. 4A and 4B, in the fan 30 having a configuration like the fan 30a, air is pressure-fed, sucked, and exhausted and a wind 39 (illustrated by the thick arrow in FIG. 4A) is generated from one side to the other side, that is, to one side Xa in a direction X, in an annular opening portion 38 between the casing 31 and the hub 33, with the rotation of the wings 34 in a predetermined shape located in the opening portion 38. An opening area A2 of the opening portion 38 in which the rotating wings 34 are located, that is, a portion (excluding portions of the connection bars 31a and the cover 31b supported by the connection bars 31a, the portion illustrated by the slant lines in FIG. 4B) through which the wind of the fan 30 passes through, is one of parameters that determine an air volume of the fan 30.

Here, the fan 30a illustrated in FIG. 3A above is exemplified, but the same similarly applies to the fan 30b illustrated in FIG. 3B above. That is, in the fan 30 having a configuration like the fan 30b, air is pressure-fed, sucked, and exhausted and the wind 39 is generated from one side to the other side in the annular opening portion 38 between the casing 31 and the hubs 33 and 36 with the rotation of the wings 34 and 37 in a predetermined shape located in the opening portion 38. An opening area A2 of the opening portion 38 in which the rotating wings 34 and 37 are located, that is, the portion through which the wind of the fan 30 passes is one of the parameters that determine the air volume of the fan 30.

Examples of the parameters that determine the air volume of the fan 30 include a size, shape, rotation direction, rotation speed, and the like of the wing 34 or 37, in addition to the opening area A2.

Note that the fan 30 (fan 30a or 30b) may be covered with a cover provided with ventilated holes, for example, a cover provided with a large number of punching holes. In the case where the fan 30 is covered with such a cover, a sum of opening areas of the large number of punching holes may be regarded to be equivalent to the opening area A2 of the opening portion 38 of the fan 30, and the opening area A2 may be regarded as an opening area as a parameter that determines the air volume of the fan 30. Alternatively, from the viewpoint of suppressing a loss of the air volume by the cover, a large number of punching holes having a total area that is not significantly different from or is regarded to be equivalent to the opening area A2 of the opening portion 38 of the fan 30 may be provided.

Next, the muffler 40 mounted in the electronic device main body 10 will be described.

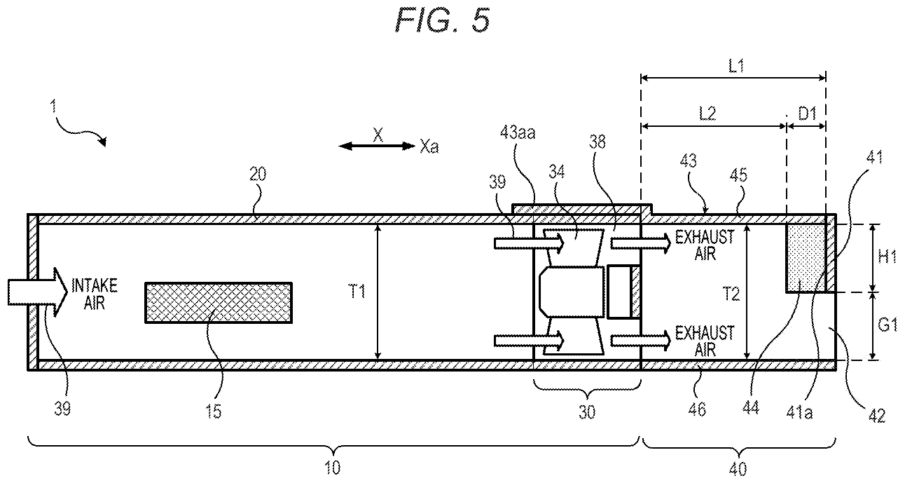

FIG. 5 is a view for describing an example of the electronic device provided with a muffler according to the first embodiment. FIG. 5 schematically illustrates a cross-sectional view of a main part of an example of the electronic device equipped with a muffler. FIG. 5 schematically illustrates a cross-sectional view of a main part when cut in a thickness direction of the device at the position of the V-V line in FIG. 2B.

As illustrated in FIG. 5, the electronic device 1 includes the electronic device main body 10 and the muffler 40 mounted therein. In the electronic device main body 10, a heat-generating electronic component 15 including a circuit board, a semiconductor element mounted on the circuit board, and the like, are built in the housing 20. The fan 30 is provided on the back side in such an electronic device main body 10. The muffler 40 is provided on the back side of the electronic device main body 10 in which the fan 30 is provided. The muffler 40 is fixed to the electronic device main body 10 by a method such as fastening with screws, bonding with an adhesive or the like, or welding. Such fixation of the muffler 40 to the electronic device main body 10 by fastening or the like can be performed using a running-on portion 43aa. The running-on portion 43aa may be used for aligning the muffler 40 with respect to the electronic device main body 10. The muffler 40 may be attachably and detachably provided with respect to the electronic device main body 10.

In the electronic device main body 10, the electronic component 15 in the housing 20 generates heat with the operation of the electronic device main body 10. In the electronic device main body 10, external air having a relatively low temperature is taken into the housing 20 from the front side with the rotation of the fan 30. The electronic component 15 in the housing 20 is cooled by heat exchange between the relatively low-temperature air taken into the housing 20 and the heat-generated electronic component 15 in the housing 20. The air inside the housing 20, which has become relatively hot due to the heat exchange with the electronic component 15, is exhausted to the outside of the housing 20 by the rotating fan 30. In the electronic device main body 10, a stable operation with suppressed overheating of the heat-generating electronic component 15 and suppressed performance deterioration and breakdown caused by the overheating is implemented using the air flow caused by the intake and exhaust air by the fan 30, that is, the wind 39 flowing toward the one side Xa in the direction X.

In the electronic device main body 10, sound is generated with the rotation of the fan 30 and the exhaust air. Meanwhile, in recent years, the heating value in the electronic device main body 10 tends to increase with higher performance, higher functionality, higher integration, higher density implementation, smaller size, thinner size, and the like of the electronic component 15 to be mounted. To cope with the increasing heating value, when the air volume by the fans 30 is increased by increasing the size or the number of the fans 30 or increasing the rotation speed of the fans 30, the sound generated from the electronic device main body 10 also increases. For example, there are some cases where the sound generated from the electronic device main body 10 becomes a sound pressure level exceeding Network Equipment Building System (NEBS) regulations (A-weighting sound pressure level of 78 dB or less at 27° C.) or European Telecommunications Standards Institute (ETSI) regulations (A-weighting sound pressure level of 75 dB or less at 23° C.).

To suppress the sound generated from the electronic device main body 10, as illustrated in FIG. 5, the muffler 40 is mounted in the electronic device 1 on the back side where the fans 30 are provided, that is, on the one side Xa (also referred to as an air-blowing direction of the fans 30) in the direction X on an air-blowing side of the fans 30. The muffler 40 includes the duct 43 having the wall portion 41 facing the fans 30 provided on the back side in the electronic device main body 10 with a certain distance, and the sound absorbing material 44 provided on an inner surface 41a of the wall portion 41 facing the fans 30. The duct 43 is further provided with the opening portion 42 facing the fans 30 together with the wall portion 41 provided with the sound absorbing material 44 on the inner surface 41a.

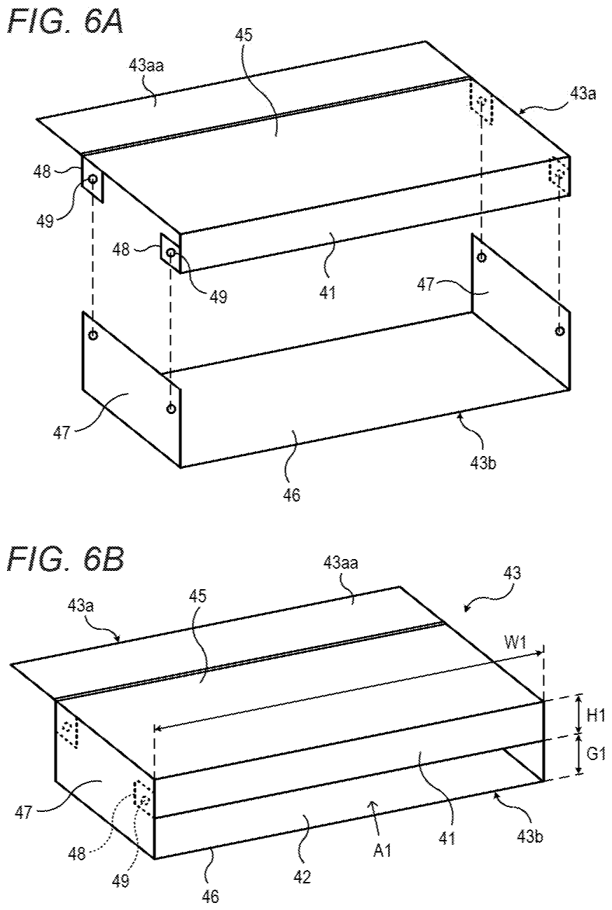

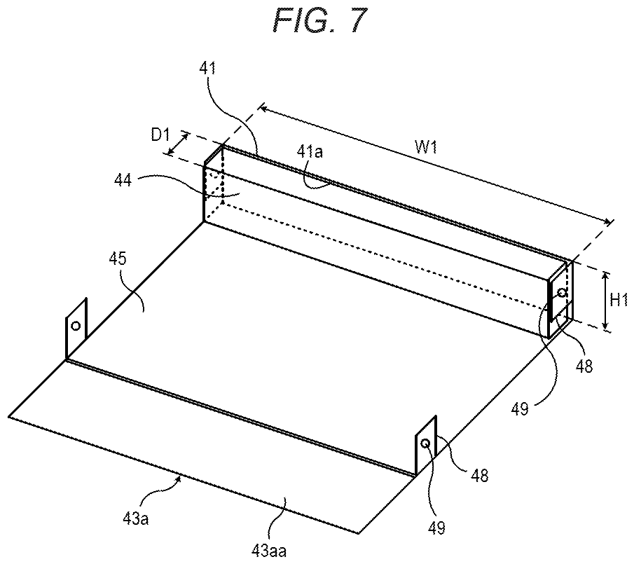

The duct 43 and the sound absorbing material 44 of the muffler 40 will be described with reference to FIG. 5 and following FIGS. 6A, 6B and 7.

FIGS. 6A and 6B are views for describing a configuration example of the duct of the muffler according to the first embodiment. FIG. 6A schematically illustrates an exploded perspective view of a main part of an example of the duct. FIG. 6B schematically illustrates a perspective view of the main part of the example of the duct after assembly. Furthermore, FIG. 7 is a view for describing the sound absorbing material provided in the duct of the muffler according to the first embodiment. FIG. 7 schematically illustrates a perspective view of a main part of an example of the duct provided with the sound absorbing material.

The duct 43 of the muffler 40 includes, for example, a plate material 43a and a plate material 43b as illustrated in FIGS. 6A and 6B.

As illustrated in FIG. 6A, the one plate material 43a includes a plate portion (here referred to as a “top plate”) 45 and the wall portion 41 provided at one end (one end of the fans 30 in the air-blowing direction). Note that the wall portion 41 illustrated in FIG. 6A is, for example, one sheet of plate facing the fans 30, in this example, the seven fans 30 (FIG. 2A) provided on the back side of the electronic device main body 10.

The other plate material 43b includes a plate portion (here referred to as a “bottom plate”) 46 and plate portions (here referred to as “side plates”) 47 provided at both ends (both ends of the fans 30 in a direction orthogonal to the air-blowing direction) of the plate material 43b.

The top plate 45 and the wall portion 41 of the plate material 43a are each provided with fixing portions 48 for fixing the plate material 43a to the plate material 43b. The fixing portions 48 of the plate material 43a and the side plates 47 of the plate material 43b are each provided with screw holes or holes 49 into which screws can be inserted at positions corresponding to each other.

As illustrated in FIG. 6B, for example, the plate material 43a is brought to face the plate material 43b such that the fixing portions 48 are located inside the side plate 47, and the positions of the mutual holes 49 are aligned with each other. Then, a screw (not illustrated) is screwed into the holes 49, or a screw is inserted and a tip side is fixed with a nut (not illustrated), so that the plate material 43a and the plate material 43b are fixed and integrated to form the duct 43.

In the duct 43, as illustrated in FIGS. 6A and 6B and FIG. 5 above, a height H1 (internal dimension 25 mm as an example) of the wall portion 41 from the top plate 45 is smaller than a height (corresponding to a thickness T1 (inner dimension) of the electronic device main body 10) of the side plates 47 from the bottom plate 46. In the duct 43, the opening portion 42 having a height. G1 (inner dimension 17 mm as an example) corresponding to a difference between the height H1 of the wall portion 41 and the height of the side plates 47 is formed on the air-blowing side of the fans 30. The wall portion 41 of the duct 43 is set to have a fixed width W1 (corresponding to the width of the electronic device main body 10, inner dimension 400 mm as an example), for example, and is provided such that an opening area A1 of the opening portion 42 becomes the same as a predetermined value, for example, the opening area A2 of the opening portions 38 of the fans 30. The wall portion 41 of the duct 43 is provided at a position of a fixed distance L1 (inner dimension 57 mm as an example) from the fan 30. The height of the side plate 47 from the bottom plate 46 of the duct 43, that is, an inner dimension T2 of the duct 43 in the thickness direction, which is an interval between the top plate 45 and the bottom plate 46, is set to be the same as the thickness of the electronic device main body 10, that is, the inner dimension T1 of the electronic device main body 10 in the thickness direction.

As illustrated in FIGS. 7 and 5, the sound absorbing material 44 is provided on the inner surface 41a of the wall portion 41 of the duct 43. Urethane foam, glass wool, rubber, plastic, or the like is used for the sound absorbing material 44. For example, a material having relatively low density of about 21 to 25 kg/m² is used for the sound absorbing material 44.

Here, considered is a case in which the sound absorbing material 44 is provided with a predetermined thickness D1 to cover the entire inner surface 41a of the wall portion 41, in this example, the entire inner surface 41a of the one plate-like wall portion 41 facing the seven fans 30 (FIG. 2A), as illustrated in FIG. 7, for example. The sound absorbing material 44 is provided on the inner surface 41a of the wall portion 41 with, for example, a rectangular plane size of the height H1×the width W1 (corresponding to the plane size of the wall portion 41) and the thickness D1 (20 mm as an example). In the muffler 40, a distance L2 from an end of the fan 30 on the side of the sound absorbing material 44 to an end of the sound absorbing material 44 on the side of the fan 30 is set to fall within a predetermined range.

It is often assumed that sound from a sound source is randomly incident on a sound absorbing material. For example, when considering a sound absorption coefficient of a sound absorbing material in a building material or the like, a measurement result with a reverberation room method sound absorption coefficient (random incidence sound absorption coefficient) is used. Regarding the reverberation room method sound absorption coefficient, for example, the following document a, “Comparison between reverberation room method sound absorption coefficient and normal incidence sound absorption coefficient” (Tokyo Metropolitan Industrial Technology Research Institute Research Report, No. 6, 2011) is known. The document describes that, in the reverberation room method, the sound absorption coefficient is measured to be large in a material having a large area due to the influence of inflow of sound energy from a peripheral portion of a sample, which is called “area effect”.

Meanwhile, in the case of using the sound absorbing material in the electronic device 1 as described above, the purpose of the electronic device 1 is to implement predetermined processing, and from the viewpoint that it is favorable that a space not contributing to the implementation of the processing is small, it is rare to use the sound absorbing material with a large area. The above-described influence of the area effect can be said to become smaller or be gone as the area of the sound absorbing material to be used becomes smaller.

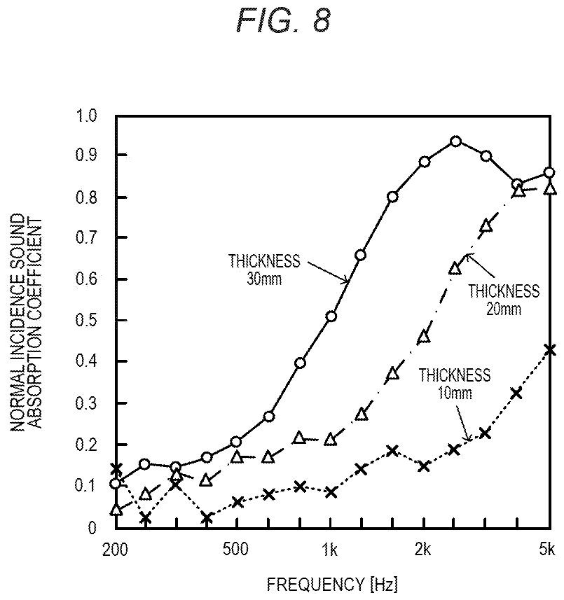

By the way, regarding the sound absorption coefficient of a sound absorbing material, for example, the following document b, “correspondence between reverberation room method and normal incidence sound absorption coefficient” (Acoustic Materials, No. 15, 1961) is known. Furthermore, FIG. 8 is a diagram illustrating an example of a relationship between a frequency and a normal incidence sound absorption coefficient for sound absorbing materials having different thicknesses. FIG. 8 illustrates an example of results of measuring the normal incidence sound absorption coefficient of sound in a frequency range of 200 Hz to 5 kHz for three types of low-density urethane foam (density 23±2 kg/m²) with thicknesses of 10 mm, 20 mm, and 30 mm.

In a case of comparing the reverberation room method sound absorption coefficient (the document b above) and the normal incidence sound absorption coefficient (FIG. 8) under similar sample conditions, the reverberation room method sound absorption coefficient tends to be higher than the normal incidence sound absorption coefficient. However, when the sound absorbing material is used in a small area and the area effect becomes small or is gone as in the case where the sound absorbing material is used in the above electronic device 1, it is expected that the sound absorption coefficient will be significantly lower when the sound absorbing material is actually used in the above electronic device 1 than a value obtained by the reverberation room method.

Therefore, adopting a structure of causing sound to be vertically incident on a sound absorbing material having a size that can make the area effect to become small or be gone to a muffler is considered. As a basic concept, the sound is randomly incident on the sound absorbing material when the distance from the sound source is long, and the sound is vertically incident on the sound absorbing material when the distance from the sound source is short. In the case of causing the sound to be vertically incident on the sound absorbing material to obtain a sound absorbing effect, it is important to sufficiently shorten the distance between the sound absorbing material and the sound source. In other words, the distance between the sound absorbing material and the sound source can be made sufficiently short if the light can be vertically incident and the sound absorbing effect can be obtained. Furthermore, the sound absorbing material does not need to be further provided around a region where the sound is vertically incident if the distance between the sound absorbing material and the sound source is sufficiently shortened, and the sound is vertically incident on the sound absorbing material and the sound is not randomly incident on the sound absorbing material.

The muffler 40 of the above electronic device 1 is designed and manufactured on the basis of such an idea.

In the muffler 40, the wall portion 41 of the duct 43 is provided at the position facing the fans 30, and the sound absorbing material 44 is provided on the inner surface 41a of the wall portion 41. For example, the inner surface of the duct 43 excluding the inner surface 41a of the wall portion 41 may be exposed without the sound absorbing material 44.

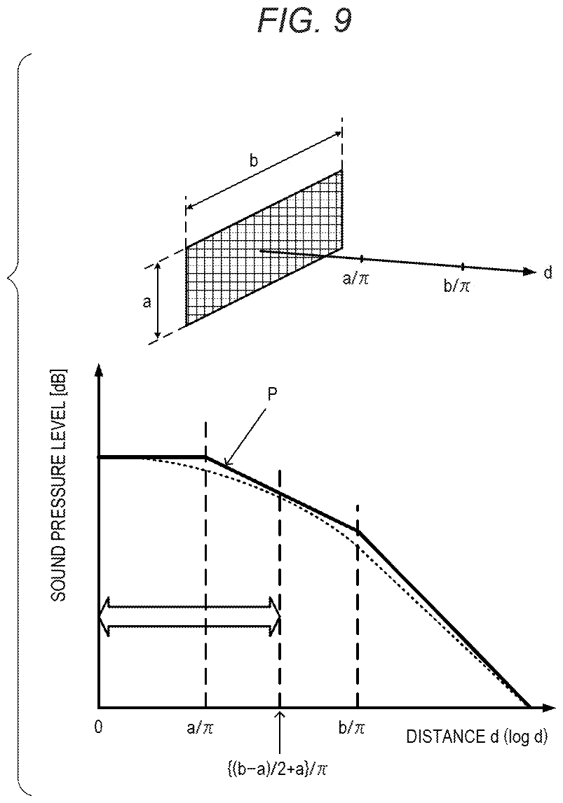

The distance L2 from the fan 30 to the sound absorbing material 44 is set to a distance in which the sound of the fan 30 is vertically incident on the sound absorbing material 44 or a probability of vertical incidence is high. Here, FIG. 9 is a diagram and a graph illustrating an example of a relationship between a distance from a sound source and attenuation of sound. FIG. 9 schematically illustrates attenuation of a sound pressure level [dB] of sound generated from a planar sound source with a length a in a short direction and a length b (>a) in a long direction with respect to a distance d [m].

As illustrated in FIG. 9, the sound has a characteristic that an attenuation behavior changes as the distance from a vicinity of the sound source increases. It is said that a characteristic of general waves are attenuated in inverse proportion to the square of the distance, but sound has a characteristic that it does not randomly diffuse and propagate near the sound source. The attenuation of the sound generated from the planar sound source with the rectangular plane size a×b is represented by an approximate expression P as illustrated in FIG. 9, and it can be considered that the sound is not attenuated in a region where the distance from the sound source is a/n or less (a region that can be regarded as a planar sound source). In a region where the distance from the sound source is from a/n to b/n, the sound source is regarded as a linear sound source, and in a region where the distance from the sound source is b/n or more (a region sufficiently distant from the sound source), the sound source is regarded as a point sound source. The region distant from the sound source by bin or more is a region where the sound randomly propagates.

The region where the distance from the sound source is a/n or less can be considered as a region where the sound vertically propagates from the sound source. Substantially, a region (the region illustrated by the thick arrow in FIG. 9) where the distance from the sound source is up to an intermediate value between a/n and b/n (={(b−a)/2+a}/n) can be regarded as a region where the sound vertically propagates from the sound source, a region where the probability of the sound vertically propagating from the sound source is high, or a region in which the sound vertically propagating from the sound source is superior to randomly propagating sound.

This is adopted in the above electronic device 1. That is, the plane size on the back side of the electronic device main body 10 where the fans 30 as a sound source are provided, that is, the plane size of the region surface of the electronic device main body 10 where the fans 30 are provided is set to the thickness T1 (the length a in the short direction)×the width W1 (the length b in the long direction). In the case where a plurality of (seven in this example) fans 30 is provided, the plane size on the back side of the electronic device main body 10 that becomes a sound source, that is, the plane size of the region surface of the electronic device main body 10 where the plurality of fans 30 is provided is set to the thickness T1 (the length a in the short direction)×the width W1 (the length b in the long direction). At this time, in a range where the distance L2 from the plurality of fans 30 to the sound absorbing material 44 at an opposite position of the fans 30 is L2<{(W1−T1)/2+T1}/n, it can be considered that the sound is vertically incident on the sound absorbing material 44 or the probability of the sound being vertically incident on the sound absorbing material 44 is high. Note that the distance L2 is set to be longer than the thickness T1 of the electronic device main body 10 for the convenience of air blowing. In the above electronic device 1, the distance L2 from the plurality of fans 30 to the sound absorbing material 44 at the opposite position of the fans 30 is desirably set to the range of T1<L2<{(W1−T1)/2+T1}/n.

As an example, in the case of the electronic device 1 having the electronic device main body 10 with the thickness T1=42 mm (the length a in the short direction) and the width W1=400 mm (the length b in the long direction), the plane size of the region surface where the plurality of fans 30 is provided is T1×W1, and T1/n=13 mm (a/n) and W1/n=127 mm (b/n). Therefore, it can be said that the sound from the plurality of fans 30 (sound source) to the sound absorbing material 44 can be made vertically incident on the sound absorbing material 44, or the probability of the sound being vertically incident on the sound absorbing material 44 can be increased, when the distance L2 from the probability of fans 30 is set to a range of 42 mm<L2<70 mm (=(127 mm−13 mm)/2+13 mm).

Furthermore, the opening portion 42 provided in the duct 43 together with the wall portion 41 having the sound absorbing material 44 provided on the inner surface 41a is set on the basis of the size of the opening portion 38 of the fan 30, that is, the size of the portion through which the wind passes. To suppress generation of wind noise due to the air blown from the fans 30, the opening portion 42 of the duct 43 is desirably set not to be narrower than the area of the narrowest portion in an air passage. Since an air-blowing resistance of the air passage is determined by the narrowest portion, the muffler 40 can be attached without redesigning the air blowing of the electronic device main body 10 by setting the opening portion 42 not to be narrower than the area of the narrowest portion. Furthermore, if the opening portion 42 is set to be narrower than the area of the narrowest portion of the air passage, new wind noise is generated and the amount of noise to be reduced by the muffler 40 increases. Therefore, the opening portion 42 is desirably set not to be narrower than the narrowest portion. In the electronic device main body 10, the narrowest portion in the air passage downstream of the fans 30 is the opening portions 38 of the fans 30. Therefore, in the above electronic device 1, the opening area A1 of the opening portion 42 of the muffler 40 is set to a value equal to or larger than the opening area A2 of the opening portions 38 of the fans 30.

Note that, in the above electronic device, the sound more easily leaks to the outside, and the sound absorbing material 44 facing the fans 30 becomes smaller and the region on which the sound is vertically incident becomes smaller, as the opening area A1 of the opening portion 42 of the muffler 40 is made larger. From this point of view, in the above electronic device 1, the opening area A1 of the opening portion 42 of the muffler 40 is set to the same or equivalent value to the opening area A2 of the opening portions 38 of the fans 30.

In the above electronic device 1, a plurality of (seven in this example) fans 30 is provided on the back side of the electronic device main body 10. In this case, the opening area A1 of the opening portion 42 of the muffler 40 is set to the same or equivalent value to the opening area A2 of the opening portion 38 of one fan 30×the number of fans 30 (A1=A2×7 in this example), that is, the total opening area A2 of the opening portions 38 (the portion where the wind passes through) of the plurality of fans 30.

When the opening area A1 of the opening portion 42 of the muffler 40 is determined, the height G1 of the opening portion 42 is determined, and when the height G1 is determined, the height H1 (=T1−G1) of the wall portion 41 and the sound absorbing material 44 on the inner surface 41a of the wall portion 41 is determined. As an example, in the above electronic device 1, the height. G1=17 mm and the height H1=25 mm.

Furthermore, the volume of the sound absorbing material 44 provided in the muffler 40 is desirably set to be as small as possible. For example, when a large-volume sound absorbing material 44 is provided on the inner surface of the duct 43 of the muffler 40, and the sound absorbing material 44 presses the air passage in the duct 43, the air-blowing resistance of the fans 30 becomes high. Noise can be reduced by the muffler 40 provided with the large-volume sound absorbing material 44 on the inner surface of the duct 43, but a predetermined cooling air volume is not able to be obtained, and when the air volume of the fans 30 is increased in order to secure the predetermined cooling air volume, the noise becomes large, which is a vicious cycle.

In the above electronic device 1, the volume of the sound absorbing material 44 provided in the muffler 40 is desirably set to be equal to or lower than 50% of the volume of the duct 43 from the viewpoint of suppressing pressure on the air passage in the duct 43 and an increase in the air-blowing resistance of the fans 30. As an example, in the above electronic device 1, the sound absorbing material 44 having the thickness D1=20 mm is provided on the inner surface 41a of the wall portion 41 having the predetermined height H1 of the duct 43. A volume ratio of the sound absorbing material 44 becomes 21% when the volume of the sound absorbing material 44 is set to the thickness D1×the height T1×the width W1=20 mm×25 mm×400 mm, and the volume of the duct 43 is set to the length L1×the thickness T1×the width W1=57 mm×42 mm×400 mm.

When the thickness D1 of the sound absorbing material 44 of the muffler 40 is determined and the distance L2 from the fans 30 to the sound absorbing material 44 at the opposite position of the fans 30 is determined, as described above, the position of the wall portion 41 where the sound absorbing material 44 is provided (the distance L1 from the fans 30 or the length of the duct 43) is determined. Alternatively, when the distance L1 from the fans 30 to the wall portion 41 of the muffler 40 is determined and the distance L2 from the fans 30 to the sound absorbing material 44 is determined, the thickness D1 of the sound absorbing material 44 may be determined such that the volume ratio becomes equal to or smaller than 50%.

Next, the muffling effect of the muffler 40 designed and manufactured as described above will be described.

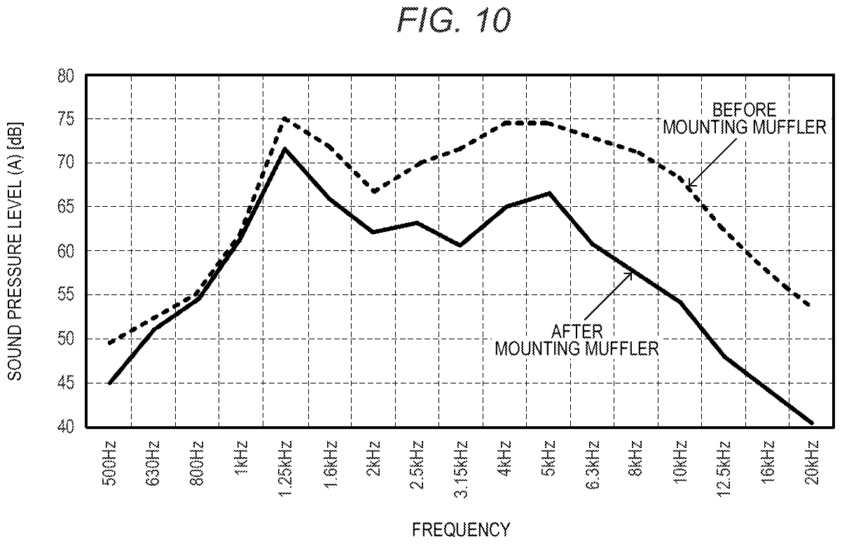

FIG. 10 is a graph illustrating an example of measurement results of the sound pressure level of sound generated by the electronic device before and after mounting the muffler. The sound pressure level (A-weighting sound pressure level, sound pressure level (A)) was measured on the basis of the ISO7779 standard (noise measurement for an information technology device).

In FIG. 10, it was observed that the A-weighting sound pressure level of the electronic device 1 after mounting the muffler 40 in the electronic device main body 10 “after mounting muffler” in the graph) exhibits a tendency of a smaller value than the A-weighting sound pressure level before mounting the muffler 40 (“before mounting muffler” in the graph) in a frequency range of 500 Hz to 20 kHz. Moreover, it was observed that the electronic device 1 after mounting the muffler 40 in the electronic device main body 10 has the A-weighting sound pressure level that falls below a predetermined specified value, for example, an NEBS specified value or an ETSI specified value. Furthermore, the temperature rise of the electronic component 15 such as the processor built in the electronic device main body 10 was about 2° C., and the influence of heat and overheating on the electronic component 15 was hardly observed.

It was observed that the above-described effect can be obtained where the A-weighting sound pressure level after mounting the muffler 40 is lower than the A-weighting sound pressure level before mounting the muffler 40, and moreover, falls below a predetermined specified value, in the case where the distance L2 from the fans 30 to the sound absorbing material 44 falls within the range of T1<L2<{(W1−T1)/2+T1}/n.

Here, for comparison, other muffling technologies will be described.

As other muffling technologies, for example, technologies described in the documents such as Japanese Laid-open Patent Publication No. 2008-270372 and Japanese Laid-open Patent Publication No. 2015-148714 are known.

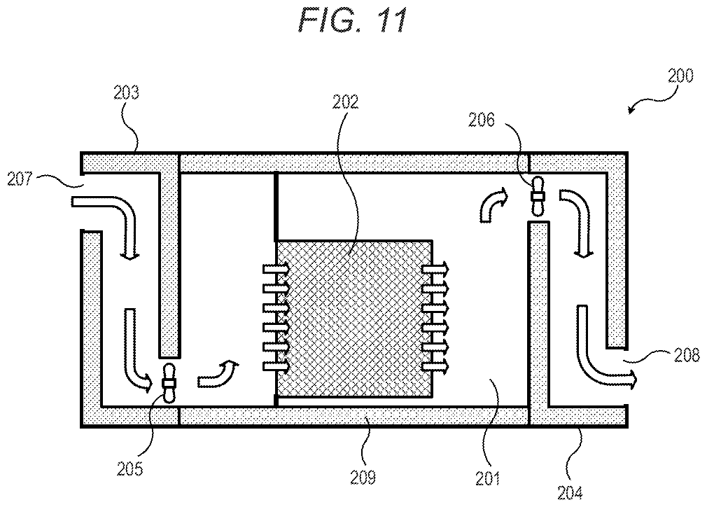

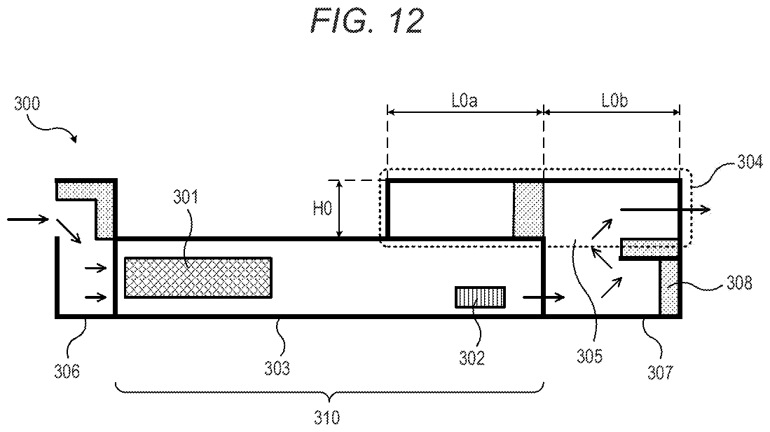

FIG. 11 is a view for describing an example of a past electronic equipment storage box. FIG. 11 schematically illustrates a cross-sectional view of a main part of the example of the electronic equipment storage box. Furthermore, FIG. 12 is a view for describing an example of past electronic equipment provided with a duct. FIG. 12 schematically illustrates a cross-sectional view of a main part of the example of the electronic equipment provided with the duct.

An electronic equipment storage box 200 illustrated in FIG. 11 is also referred to as a silent rack. Electronic equipment 202 such as a server computer is housed in a rack space 201 of the electronic equipment storage box 200. The electronic equipment storage box 200 is provided with ducts 203 and 204 and fans 205 and 206 on the front and rear (front and back) sides of the electronic equipment 202. When the electronic equipment 202 operates, relatively low-temperature air outside the electronic equipment storage box 200 is taken into the duct 203 through an intake port 207 by the operation of the fan 205, and the air is taken into the electronic equipment 202 through the duct 203. The air used to cool the electronic device in the electronic equipment 202 and exhausted from the electronic equipment 202 at a relatively high temperature is exhausted to the duct 204 by the operation of the fan 206, and is exhausted to the outside of the electronic equipment storage box 200 through an exhaust port 208 of the duct 204.

In the electronic equipment storage box 200 illustrated in FIG. 11, a wall material (outer wall) having high sound insulation is used for the rack space 201 and the ducts 203 and 204, and a sound absorbing material 209 is provided in the rack space 201 and on inner surfaces of the ducts 203 and 204. Moreover, the length of the duct 203 from the intake port 207 to the fan 205 and the length of the duct 204 from the fan 206 to the exhaust port 208 are secured to a certain length or more. In this way, the electronic equipment 202 is surrounded by the wall material having high sound insulation, and a duct structure having a high sound absorbing effect is adopted for the intake and exhaust portions, so that a high muffling effect is implemented. However, such electronic equipment storage box 200 needs a larger installation space than the electronic equipment 202 that becomes a sound source. For example, there are some cases where the volume of the electronic equipment storage box 200 becomes five times or more the volume of the electronic equipment 202, and the installation location may be restricted.

Furthermore, an electronic device 300 illustrated in FIG. 12 includes a housing 303 in which an electronic component 301 and the fan 302 are housed, and a duct 304 provided on the exhaust side of the housing 303. When the fan 302 is driven, the outside air is taken in, flows into the duct 304 through the inside of the housing 303, and is further exhausted to the outside of the duct 304. In the duct 304, one end side is a free end and the other end side is a fixed end, and a length L0a from a communication port 305 to the other end is set such that sound propagating from an exhaust portion 307 through the communication port 305 in a middle portion creates a wave that cancels a standing wave generated in the entire duct 304. A sound absorbing material 308 is provided in an intake portion 306, the exhaust portion 307, and at a predetermined position in the duct 304.

In the electronic device 300 illustrated in FIG. 12, a high muffling effect is implemented by a combination of sound interference and sound absorption due to the length of the duct 304. However, to interfere with sound, a space having a length L0b in the rear of an electronic device main body 310 and a height H0 above the electronic device main body 310 is needed. For example, to provide the duct 304 that interferes with sound, a relatively large space with the distance L0a=160 mm, the distance L0b=150 mm, and the height H0=40 mm may be needed. In the case where the thickness (inner dimension) of the electronic device main body 310 is set to 42 mm, which is the same as the value (inner dimension) given as an example of the above electronic device main body 10 of the first embodiment, a space having a size three times the thickness of the electronic device main body 310, and having an equivalent size above the electronic device main body 310 is needed in the rear of the electronic device main body 310.

As described above, in the past muffling technology, a relatively large space is needed to implement muffling. That is, the above electronic equipment storage box 200 (FIG. 11) needs a large space to cover the entire electronic equipment 202 and further increase the duct length in the duct structure where the sound absorbing material is provided on the inner surface to enhance the muffling effect. Furthermore, in the interference-type duct structure as seen in the above electronic device 300 (FIG. 12), a space for interfering sound is needed. Moreover, until now, it has been thought that a sound absorbing material having a certain thickness and area is needed for sound absorption. Therefore, the sound absorbing material in the muffler has had a large volume, or the muffler has been large in order to suppress the pressure on the air passage by the large-volume sound absorbing material. The reason why the past sound muffling technology needs a relatively large space is mainly because it is assumed that the sound is randomly incident on the sound absorbing material.

In contrast, in the above electronic device 1 according to the first embodiment, the muffler 40 having an equivalent thickness to the thickness T1 of the electronic device main body 10 is mounted on the back side of the electronic device main body 10 where the fans 30 are provided. The muffler 40 is provided with the duct 43 having the wall portion 41 located facing the fans 30 and the opening portion 42 on the air-blowing side of the fans 30, and the sound absorbing material 44 is provided on the inner surface 41a of the wall portion 41. For example, the sound absorbing material may not be provided on the inner surface of the duct 43 excluding the wall portion 41. Then, for example, the distance L2 from the fans 30 to the sound absorbing material 44 is set such that sound generated by the fans 30 is vertically incident on the sound absorbing material 44 of the wall portion 41 or has a high probability of being vertically incident on the sound absorbing material 44. Moreover, the opening area A1 of the opening portion 42 of the duct 43 and the like are set on the basis of the opening area A2 of the opening portions. 38 (the portion through which the wind passes) of the fans 30. In the muffler 40, the distance L2 from the fans 30 to the sound absorbing material 44 can be set to fall in the range of T1<L2<{(W1−T1)/2+T1}/n on the basis of the thickness T1 and the width W1 of the electronic device main body 10, that is, the plane size of the region surface (planar sound source) where the fans 30 are provided. According to the configuration as described in the above first embodiment, the muffler 40 small in size and using a small amount of the sound absorbing material 44 is implemented. Moreover, the small electronic device 1 having such a muffler 40 mounted in the electronic device main body 10 is implemented.

Next, a modification of the above electronic device 1 will be described.

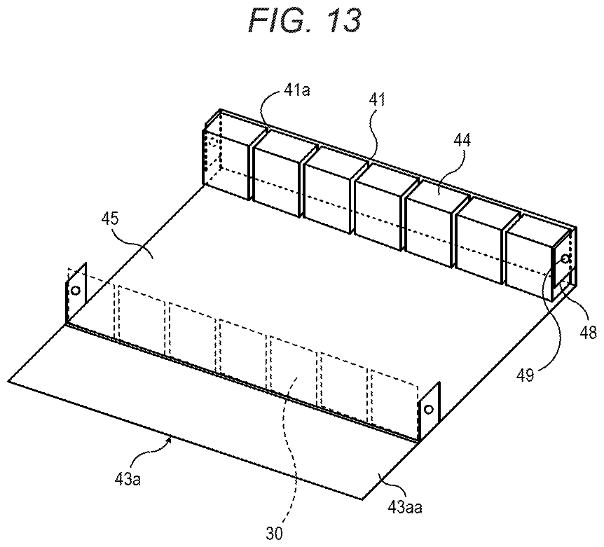

FIG. 13 is a view for describing a first modification of the electronic device according to the first embodiment. FIG. 13 schematically illustrates a perspective view of a main part of a duct provided with a sound absorbing material according to the first modification.

As illustrated in FIG. 7 above, the muffler 40 can be provided with, on the plate material 43a, the sound absorbing material 44 so as to cover the entire inner surface 41a of one sheet of plate-like wall portion 41 facing the plurality of fans 30 (seven fans 30 in this example) In addition, as illustrated in FIG. 13, the muffler 40 may be provided with the sound absorbing materials 44 on the plate material 43a at positions respectively facing the plurality of fans 30 (illustrated by the chain line for convenience in FIG. 13). Such a plate material 43a is fixed and integrated with the other plate material 43b by using the fixing portions 48 and the holes 49 to form the duct 43. Even with the arrangement of the sound absorbing materials 44 as illustrated in FIG. 13, the sound generated in the plurality of fans 30 can be brought to be vertically incident on the plurality of sound absorbing materials 44, or the probability of vertical incidence of the sound can be increased, so that the sound can be effectively absorbed.

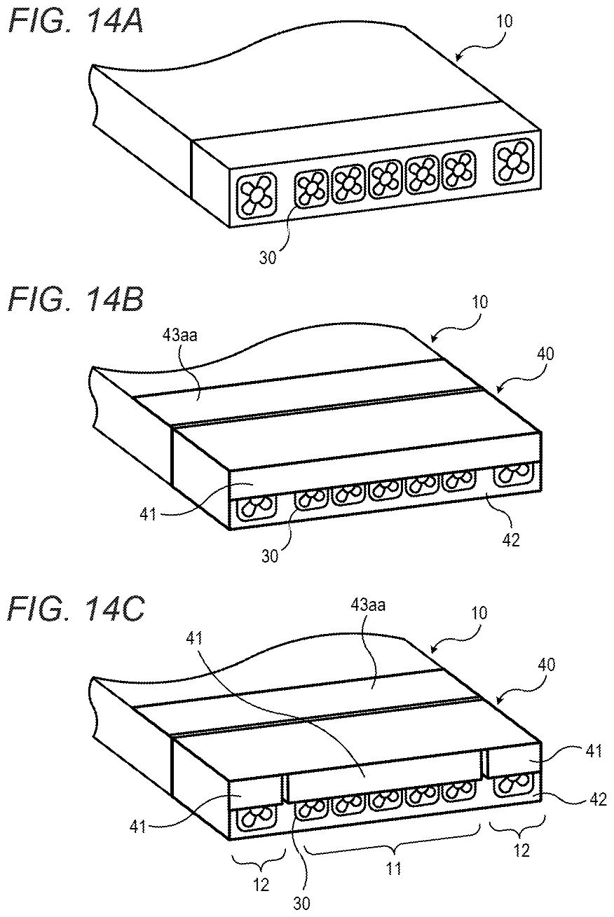

FIGS. 14A to 14C are views for describing a second modification of the electronic device according to the first embodiment. FIG. 14A schematically illustrates a perspective view of the main part of the electronic device main body before mounting a muffler. FIG. 14B schematically illustrates a perspective view of the main part of the electronic device in which the above muffler is mounted on the electronic device main body, FIG. 14C schematically illustrates a perspective view of the main part of the electronic device in which the muffler according to the second modification is mounted on the electronic device main body.

The muffler 40 provided with one sheet of wall portion 41 facing the plurality of fans 30, as illustrated in FIG. 14B, can be mounted on the electronic device main body 10 provided with the plurality of (seven in this example) fans 30 on the back side, as illustrated in FIG. 14A. In addition, the muffler 40 provided with the wall portions 41 divided into a plurality of sections, as illustrated in FIG. 14C, can be mounted on the electronic device main body 10, as illustrated in FIG. 14A. As an example, FIG. 14C illustrates the muffler 40 divided into the wall portion 41 facing the system fan region 11 and the wall portions 41 facing the power supply fan region 12. Even if such wall portions 41 divided into the plurality of sections are provided as illustrated in FIG. 14C, the sound can be brought to be vertically incident on the sound absorbing materials 44 (not illustrated) provided on the respective inner surfaces, or the probability of vertical incident of the sound can be increased, so that the sound can be effectively absorbed.

### Second Embodiment

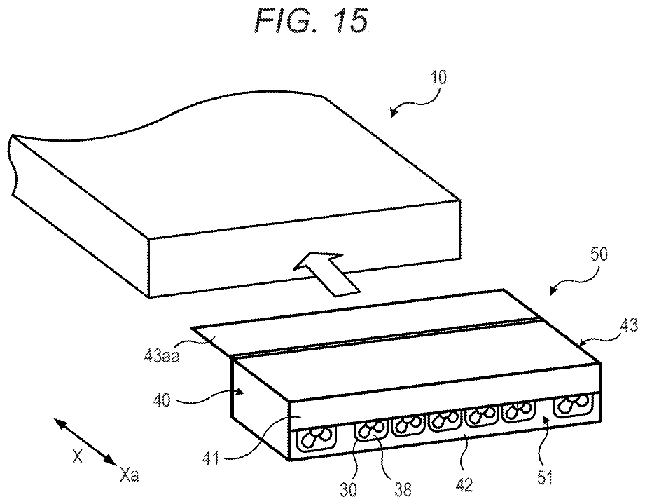

FIG. 15 is a view for describing a first example of a fan unit with a muffler according to a second embodiment. FIG. 15 schematically illustrates a perspective view of a main part of an example of a fan unit with a muffler and an electronic device main body in which the fan unit is mounted.

A fan unit 50 with a muffler illustrated in FIG. 15 includes a fan unit main body 51 provided with a plurality of fans 30 that blows air toward one side Xa in a direction X, and a muffler 40 mounted in the fan unit main body 51 on an air-blowing side of the fans 30. Note that, in the first example, the fan unit 50 with a muffler is a form of “device”, and the fan unit main body 51 is a form of “device main body”.

The fan unit main body 51 is attachable to and detachable from an electronic device main body 10. The plurality of fans 30 of the fan unit main body 51 becomes operable when the fan unit main body 51 is connected to the electronic device main body 10 to which a power is supplied from an outside, and the power is supplied from the electronic device main body 10 to the fan unit main body 51. Alternatively, the fans 30 of the fan unit main body 51 become operable when the power is directly supplied to the fan unit main body 51 from an outside even if the fan unit main body 51 is not connected to the electronic device main body 10. The muffler 40 is mounted on such a fan unit main body 51 having the plurality of fans 30. The muffler 40 having a configuration as described in the above first embodiment can be mounted.

In the fan unit 50 with a muffler, the muffler 40 having an equivalent thickness to the thickness of the fan unit main body 51 (corresponding to the thickness of the electronic device main body 10) is mounted on the back side of the fan unit main body 51 (on an air-blowing side of the fans 30). The muffler 40 is provided with a duct 43 having a wall portion 41 located facing the fans 30 and an opening portion 42 on the air-blowing side of the fans 30, and a sound absorbing material 44 (not illustrated) is provided on an inner surface of the wall portion 41. For example, the sound absorbing material may not be provided on the inner surface of the duct 43 excluding the wall portion 41. Then, for example, the distance from the fans 30 to the sound absorbing material 44 is set such that sound generated by the fans 30 is vertically incident on the sound absorbing material 44 of the wall portion 41 or has a high probability of being vertically incident on the sound absorbing material 44. Moreover, an opening area of the opening portion 42 of the duct 43 and the like are set on the basis of an opening area of opening portions 38 (a portion through which a wind passes) of the fans 30. In the muffler 40, the distance from the fans 30 to the sound absorbing material 44 can be set to fall in a predetermined range, that is, a range of T1<L2<{(W1−T1)/2+T1}/n, where the thickness of the fan unit main body 51 is T1 and the width is W1 on the basis of a plane size of a region surface where the fans 30 are provided. Thereby, the muffler 40 small in size and using a small amount of the sound absorbing material 44 is implemented. Moreover, the small fan unit 50 with such a muffler 40 mounted on the fan unit main body 51 is implemented.

When the fan unit 50 with a muffler is mounted on the electronic device main body 10 in the direction as illustrated by the thick arrow in FIG. 15, an electronic device 1 similar to that described in the above first embodiment is implemented. Thereby, the small electronic device 1 provided with the small fan unit 50 with a muffler is implemented.

The fan unit 50 with a muffler as illustrated in FIG. 15 can be applied to the same type or a different type of electronic device main body 10 to/from which the fan unit 50 is attachable/detachable. Thereby, the fan unit 50 with a muffler or the electronic device main body 10 can be replaced, and the maintainability and the versatility of the fan unit 50 with a muffler and the electronic device main body 10 can be improved.

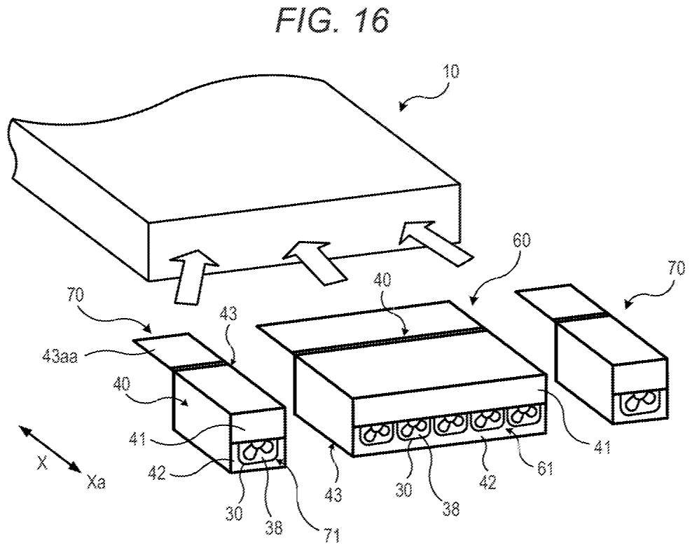

FIG. 16 is a view for describing a second example of the fan unit with a muffler according to the second embodiment. FIG. 16 schematically illustrates a perspective view of a main part of an example of a fan unit with a muffler and an electronic device main body on which the fan unit is mounted.

FIG. 16 illustrates a system fan unit 60 with a muffler provided with a plurality of fans 30, which is used as a system fan, and a plurality of (two in this example) power supply fan units 70 with a muffler each provided with one fan 30, which are used as power supply fans. Note that, in the second example, the system fan unit 60 with a muffler and the power supply fan units 70 with a muffler are each forms of “device”.

The system fan unit 60 with a muffler includes a system fan unit main body 61 provided with a plurality of fans 30 (system fans) that blows air toward one side Xa in a direction X, and a muffler 40 mounted in the system fan unit main body 61 on an air-blowing side of the fans 30. Note that, in the second example, the system fan unit main body 61 is a form of “device main body”.

The system fan unit main body 61 is attachable to and detachable from the electronic device main body 10. The plurality of fans 30 of the system fan unit main body 61 becomes operable when the power is supplied from the electronic device main body 10 to which the system fan unit main body 61 is connected or the power is directly supplied to the system fan unit main body 61. The muffler 40 having a configuration as described in the above first embodiment is mounted on such a system fan unit main body 61 provided with the plurality of fans 30.

The power supply fan unit 70 with a muffler includes a power supply fan unit main body 71 provided with one fan 30 (power supply fan) that blows air toward the one side Xa in the direction X, and the muffler 40 mounted on the power supply fan unit main body 71 on the air-blowing side of the fan 30. The power supply fan unit 70 with a muffler may include a plurality of power supply fans as the fans 30. Note that, in the second example, the power supply fan unit main body 71 is a form of the “device main body”.

The power supply fan unit main body 71 is attachable to and detachable from the electronic device main body 10. The fan 30 (one or two or more fans 30) of the power supply fan unit main body 71 becomes operable when the power is supplied from the electronic device main body 10 to which the power supply fan unit main body 71 is connected or the power is directly supplied to the power supply fan unit main body 71. The muffler 40 having a configuration as described in the above first embodiment is mounted on such a power supply fan unit main body 71 provided with the fan 30.

In each of the system fan unit 60 with a muffler and the power supply fan unit 70 with a muffler, the muffler 40 having a thickness equivalent to the thickness (corresponding to the thickness of the electronic device main body 10) of the system fan unit main body 61 or the power supply fan unit main body 71 is mounted on the back side (on the air-blowing side of the fan 30) of the system fan unit main body 61 or the power supply fan unit main body 71. The muffler 40 is provided with a duct 43 having a wall portion 41 located facing the fans 30 and an opening portion 42 on the air-blowing side of the fans 30, and a sound absorbing material 44 (not illustrated) is provided on an inner surface of the wall portion 41. For example, the sound absorbing material may not be provided on the inner surface of the duct 43 excluding the wall portion 41. Then, for example, the distance from the fans 30 to the sound absorbing material 44 is set such that sound generated by the fans 30 is vertically incident on the sound absorbing material 44 of the wall portion 41 or has a high probability of being vertically incident on the sound absorbing material 44. Moreover, an opening area of the opening portion 42 of the duct 43 and the like are set on the basis of an opening area of opening portions 38 (a portion through which a wind passes) of the fans 30. In the muffler 40, the distance from the fans 30 to the sound absorbing material 44 can be set to a predetermined range on the basis of the plane size of the region surface where the fans 30 are provided, that is, the thicknesses and widths of the system fan unit main body 61 and the power supply fan unit main body 71, according to the above-described example. Thereby, the muffler 40 small in size and using a small amount of the sound absorbing material 44 is implemented. Moreover, the small system fan unit 60 with a muffler and the small power supply fan unit 70 with a muffler having such a muffler 40 mounted on the system fan unit main body 61 and the power supply fan unit main body 71 are implemented.

When the system fan unit 60 with a muffler and the power supply fan unit 70 with a muffler are mounted on the electronic device main body 10 in the directions as illustrated by the thick arrows in FIG. 16, the electronic device 1 similar to that described in the above first embodiment is implemented. Thereby, the small electronic device 1 including the small system fan unit 60 with a muffler and the small power supply fan unit 70 with a muffler is implemented.

Each of the system fan unit 60 with a muffler and the power supply fan unit 70 with a muffler as illustrated in FIG. 16 can be applied to the same type or a different type of electronic device main body 10 to/from which the unit is attachable/detachable. Thereby, the system fan unit 60 with a muffler, the power supply fan unit 70 with a muffler, or the electronic device main body 10 can be replaced, and the maintainability and the versatility of the system fan unit 60 with a muffler, the power supply fan unit 70 with a muffler, and the electronic device main body 10 can be improved.

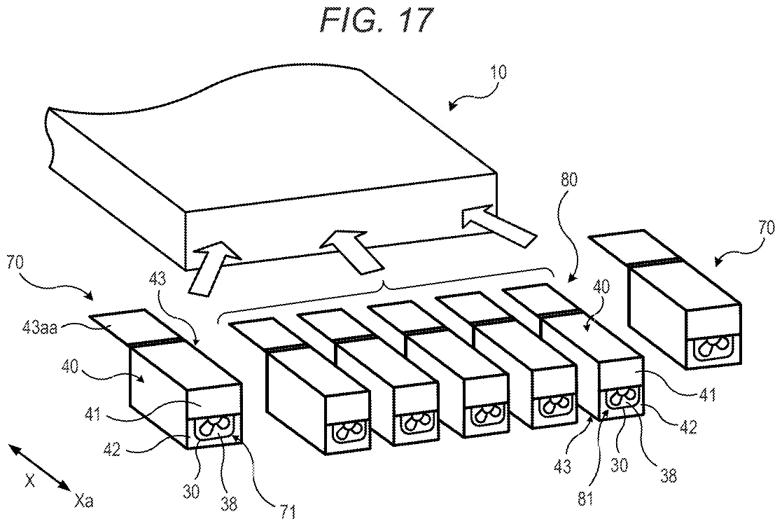

FIG. 17 is a view for describing a third example of the fan unit with a muffler according to the second embodiment. FIG. 17 schematically illustrates a perspective view of a main part of an example of a fan unit with a muffler and an electronic device main body on which the fan unit is mounted.

FIG. 17 illustrates a plurality of (five in this example) system fan units 80 with a muffler each provided with one fan 30, which are used as system fans, and a plurality of (two in this example) power supply fan units 70 with a muffler each provided with one fan 30, which are used as power supply fans. The system fan unit 80 with a muffler has a similar configuration to the system fan unit 60 with a muffler described in the above second example, except that the number of fans 30 provided in a system fan unit main body 81 is one. The small system fan unit 80 with a muffler having the small muffler 40 mounted on the system fan unit main body 81 is implemented. Note that, in the third example, the system fan unit 80 with a muffler is a form of the “device”, and the system fan unit main body 81 is a form of the “device main body”.

When the system fan unit 80 with a muffler and the power supply fan unit 70 with a muffler are mounted on the electronic device main body 10 in the directions as illustrated by the thick arrows in FIG. 17, the electronic device 1 similar to that described in the above first embodiment is implemented. Thereby, the small electronic device 1 including the small system fan unit 80 with a muffler and the small power supply fan unit 70 with a muffler is implemented.

Each of the system fan unit 80 with a muffler and the power supply fan unit 70 with a muffler as illustrated in FIG. 17 can be applied to the same type or a different type of electronic device main body 10 to/from which the unit is attachable/detachable. Thereby, the system fan unit 80 with a muffler, the power supply fan unit 70 with a muffler, or the electronic device main body 10 can be replaced, and the maintainability and the versatility of the system fan unit 80 with a muffler, the power supply fan unit 70 with a muffler, and the electronic device main body 10 can be improved.

As described above, according to the muffler 40, downsizing of the muffler 40 is implemented. Moreover, a small device having the muffler 40 mounted on the device main body is implemented. That is, the small electronic device 1 having the electronic device main body 10, the fan unit main body 51, the system fan unit main bodies 61 and 81, and the power supply fan unit main body 71 each equipped with the muffler 40, and the small fan unit 50 with a muffler, the small system fan units 60 and 80 with a muffler, and the small power supply fan unit 70 with a muffler provided in the electronic device 1 are implemented.

By implementing the small electronic device 1 using the muffler 40, the electronic equipment 100 (FIG. 1) in which the electronic device 1 is mounted can be made smaller and thinner, and the electronic equipment 100 can be installed in a relatively large space with high density such as a computer room or the like or can be installed in a relatively small space such as an office or one room of the office. Since the muffler 40 is small and has a sufficient muffling effect, it is possible to suppress noise regardless of the installation location.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A muffler provided on an air-blowing side of a fan of a device main body provided with the fan, the muffler comprising:
a duct provided on the air-blowing side of the fan and having a wall portion facing the fan; and
a sound absorbing material provided on an inner surface of the wall portion on a side of the fan, wherein
a relationship of a<L<{(b−a)/2+a}/n is satisfied where a distance from an end of the fan on a side of the sound absorbing material to an end of the sound absorbing material on a side of the fan is L, a length of a region surface, where the fan is provided, in a short direction is a, and a length of the region surface in a long direction is b, the region surface being of the device main body.

2. The muffler according to claim 1, wherein
the duct has an opening portion facing the fan, and
an area of the opening portion is same as an area of a portion through which a wind passes, the portion being of the fan.

3. The muffler according to claim 1, wherein an inner dimension of the duct in a thickness direction is same as an inner dimension of the device main body in a thickness direction.

4. An electronic device comprising:
a device main body provided with a fan; and
a muffler provided on an air-blowing side of the fan of the device main body, wherein
the muffler includes:
a duct provided on the air-blowing side of the fan and having a wall portion facing the fan, and
a sound absorbing material provided on an inner surface of the wall portion on a side of the fan, and
the muffler satisfies a relationship of a<L<{(b−a)/2+a}/n where a distance from an end of the fan on a side of the sound absorbing material to an end of the sound absorbing material on a side of the fan is L, a length of a region surface, where the fan is provided, in a short direction is a, and a length of the region surface in a long direction is b, the region surface being of the device main body.

5. The electronic device according to claim 4, wherein
the duct has an opening portion facing the fan, and
an area of the opening portion is same as an area of a portion through which a wind passes, the portion being of the fan.
